(19) United States
(12) Patent Application Publication
(10) Pub. No.: US 2025/0046048 A1
(43) Pub. Date: Feb. 6, 2025

(54) SENSING PANEL

(71) Applicant: AUO Corporation, HSIN-CHU (TW)

(72) Inventors: Xiang-Rui CHANG, HSIN-CHU (TW); Chao-Chien CHIU, HSIN-CHU (TW)

(21) Appl. No.: 18/391,730

(22) Filed: Dec. 21, 2023

(30) Foreign Application Priority Data
Aug. 1, 2023 (TW) 112128880

(51) Int. Cl. G06V 10/147; G06V 10/143; G06V 10/145; G06V 40/13; H10K 39/32

(52) U.S. Cl. CPC G06V 10/147; G06V 10/143; G06V 10/145; G06V 40/1306; H10K 39/32

(57) ABSTRACT

A sensing panel includes a substrate, a first sensor, a second sensor, a first switching element, and a second switching element. The first sensor includes a first metal electrode layer, a light-sensing layer, and a first transparent electrode layer. The first sensor is configured to receive a light and correspondingly generate a first sensing signal. The second sensor includes a second metal electrode layer, an insulating layer, and a second transparent electrode layer. The second sensor is configured to contact an object and generate a second sensing signal based on a capacitance value between the object and the second metal electrode layer. The first metal electrode layer is electrically connected to the second metal electrode layer and is electrically connected to the first switching element and the second switching element. The first transparent electrode layer is electrically connected with the second transparent electrode layer.

### CROSS-REFERENCE TO RELATED APPLICATION

This application claims priority to Taiwan Application Serial Number 112128880, filed Aug. 1, 2023, which is herein incorporated by reference.

### BACKGROUND

### Field of Disclosure

The present disclosure relates to a sensing panel, in particular to a sensing panel with optical sensing function and capacitive sensing function.

### Description of Related Art

Devices used by customs to scan passports and identify fingerprints mostly utilize optical sensors for scanning. By collecting images of passports or fingerprints and using recognition software to extract and compare features of the images, information on the passports can be obtained or the owners of the fingerprints can be determined as a security mechanism for user identification and authentication. However, due to limitations of circuit layouts and components of the optical sensing devices, their resolution in recognition and anti-counterfeiting effect are worse than capacitive sensing devices.

Accordingly, how to provide a sensing panel to solve the aforementioned problems becomes an important issue to be solved by those in the industry.

### SUMMARY

An aspect of the disclosure is to provide a sensing panel that may efficiently solve the aforementioned problems.

According to some embodiments of the present disclosure, a sensing panel includes a substrate, a first sensor, a second sensor, a first switching element, and a second switching element. The first sensor is disposed above the substrate. The first sensor includes a first metal electrode layer, a light-sensing layer, and a first transparent electrode layer. The first sensor is configured to receive a light and correspondingly generate a first sensing signal. The light-sensing layer is disposed on the first metal electrode layer. The first transparent electrode layer is disposed on the light-sensing layer. The second sensor is disposed above the substrate. The second sensor includes a second metal electrode layer, an insulating layer and a second transparent electrode layer. The second sensor is configured to contact an object and generate a second sensing signal based on a capacitance value between the object and the second metal electrode layer. The insulating layer is disposed on the second metal electrode layer. The second transparent electrode layer is disposed on the insulating layer. The first metal electrode layer is electrically connected to the second metal electrode layer and further to the first switching element and the second switching element. The first transparent electrode layer is electrically connected to the second transparent electrode layer.

In some embodiments of the present disclosure, the light-sensing layer contains silicon-rich oxide.

In some embodiments of the present disclosure, the first transparent electrode layer and the second transparent electrode layer are in contact with each other.

In some embodiments of the present disclosure, the first transparent electrode layer and the second transparent electrode layer are connected to form a transparent conductive layer. The transparent conductive layer covers the light-sensing layer of the first sensor and the insulating layer of the second sensor.

In some embodiments of the present disclosure, the light-sensing layer of the first sensor and the insulating layer of the second sensor jointly cover the first metal electrode layer and the second metal electrode layer.

In some embodiments of the present disclosure, the first switching element and the second switching element are thin film transistors. The first switching element and the second switching element include a source, a drain, and a gate, respectively. The first sensor and the second sensor are electrically connected the drain of the first switching element and the gate of the second switching element.

In some embodiments of the present disclosure, the sensing panel further includes a light source module. A side of the first transparent electrode layer and the second transparent electrode layer away from the substrate is a sensing area. The object is disposed in the sensing area. The light source module is configured to emit the light toward the sensing area, so that the light is reflected from the object through the first transparent electrode layer to the light-sensing layer.

In some embodiments of the present disclosure, the light source module is disposed on a side of the substrate away from the sensing area.

In some embodiments of the present disclosure, the insulating layer of the second sensor laterally surrounds the light-sensing layer of the first sensor.

According to some other embodiments of the present disclosure, a sensing panel includes a substrate, and a pixel array. The pixel array includes a plurality of pixel circuit units arranged in an array. Each of the pixel circuit units includes a metal layer, a transparent conductive layer, a light-sensing layer, an insulating layer, a first thin film transistor, and a second thin film transistor. The metal layer is disposed above the substrate. The transparent conductive layer is disposed above the metal layer. The light-sensing layer is disposed between the metal layer and the transparent conductive layer. The light-sensing layer is configured to receive a light. The insulating layer is disposed between the metal layer and the transparent conductive layer. The insulating layer laterally surrounds the light-sensing layer. The first thin film transistor and the second thin film transistor includes a source, a drain, and a gate, respectively. The transparent conductive layer is electrically connected to the drain of the first thin film transistor and the gate of the second thin film transistor.

In some embodiments of the present disclosure, the light-sensing layer includes silicon-rich oxide.

In some embodiments of the present disclosure, the gate of the first thin film transistor is configured to receive a driving signal.

In some embodiments of the present disclosure, the source of the first thin film transistor is configured to receive a system voltage.

In some embodiments of the present disclosure, the drain of the second thin film transistor is configured to receive a system voltage.

In some embodiments of the present disclosure, the sensing panel further includes a light source module. A side of the transparent conductive layer away from the substrate is a sensing area. The light source module is configured to emit the light towards the sensing area, so that the light is reflected from an object disposed in the sensing area through the transparent conductive layer to the light-sensing layer.

In some embodiments of the present disclosure, the light source module is disposed on a side of the substrate away from the sensing area.

In some embodiments of the present disclosure, the light-sensing layer and the insulating layer jointly cover the metal layer.

Accordingly, in the sensing panels of some embodiments of the present disclosure, by coupling the light-sensing element and the capacitive sensing element to the pixel circuit unit, both light-sensing and capacitive sensing functions can be included. As a result, when scanning images of hard copies such as passports, the light source module is activated and the light-sensing element is used for scanning. When identifying fingerprints, the capacitive sensing with better resolution and anti-counterfeiting effect is switched on. Compared with common sensing panels that only have light-sensing functions, resolution may be improved and anti-counterfeiting effects may be achieved in the sensing panels of some embodiments of the present disclosure.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a schematic diagram of a pixel circuit unit according to some embodiments of the present disclosure;

FIG. 2 is a schematic diagram of a pixel array of a sensing panel according to some embodiments of the present disclosure;

FIG. 3 is a sequence diagram of a sensing panel according to some embodiments of the present disclosure;

FIG. 4 is a sequence diagram of a sensing panel according to some embodiments of the present disclosure;

FIG. 5 is a partial cross-sectional view of a sensing panel according to some embodiments of the present disclosure; and

FIG. 6 is a partial cross-sectional view of a sensing panel according to some embodiments of the present disclosure.

### DETAILED DESCRIPTION

Reference will now be made in detail to the present embodiments of the disclosure, examples of which are illustrated in the accompanying drawings. It should be understood that there is no intent to limit example embodiments to the particular forms disclosed, but on the contrary, example embodiments are to cover all modifications, equivalents, and alternatives falling within the scope of the disclosure.

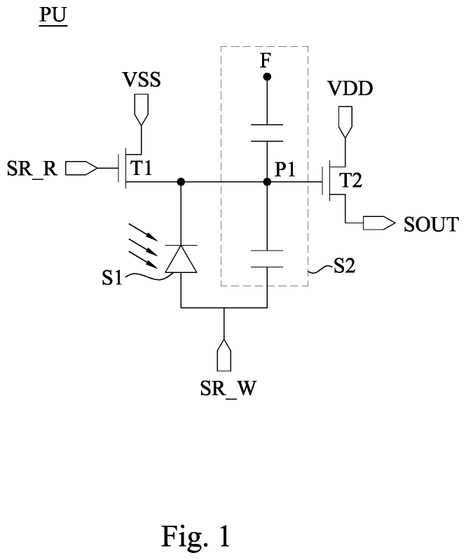

Reference is made to FIG. 1. FIG. 1 is a schematic diagram of a pixel circuit unit PU according to some embodiments of the present disclosure. As shown in FIG. 1, the pixel circuit unit PU is configured to receive a driving signal SR_R, a writing signal SR_W, a system voltage signal VSS, and a system voltage signal VDD.

The pixel circuit unit PU includes a first switching element and a second switching element. In some embodiments, as shown in FIG. 1, the first switching element is a first thin film transistor T1, and the second switching element is a second thin film transistor T2. The first thin film transistor T1 and the second thin film transistor T2 include a source, a drain, and a gate, respectively.

In some embodiments, as shown in FIG. 1, the gate of the first thin film transistor T1 is configured to receive the driving signal SR_R. In some embodiments, the source of the first thin film transistor T1 is configured to receive the system voltage signal VSS. In some embodiments, the drain of the second thin film transistor T2 is configured to receive the system voltage signal VDD.

The pixel circuit unit PU further includes a first sensor S1 and a second sensor S2. For example, as shown in FIG. 1, the first sensor S1 is a light-sensing element, and the second sensor S2 is a capacitive sensing element. In some embodiments, the second sensor S2 is configured to contact an object to be detected, such as a finger F. In some embodiments, an anode of the first sensor S1 is configured to receive the writing signal SR_W. In some embodiments, the source of the second thin film transistor T2 is configured to generate a sensing result SOUT.

As shown in FIG. 1, the first thin film transistor T1, the second thin film transistor T2, the first sensor S1, and the second sensor S2 are coupled to each other through a node P1. To be more specific, a cathode of the first sensor S1 is configured to be coupled to the node P1. The drain of the first thin film transistor T1 is configured to be coupled to the cathode of the first sensor S1 through the node P1. The gate of the second thin film transistor T2 is configured to be coupled to the cathode of the first sensor S1 and the drain of the first thin film transistor T1 through the node P1.

Similarly, as shown in FIG. 1, the second sensor S2 is coupled to the cathode of the first sensor S1, the drain of the first thin film transistor T1, and the gate of the second thin film transistor T2 through the node P1.

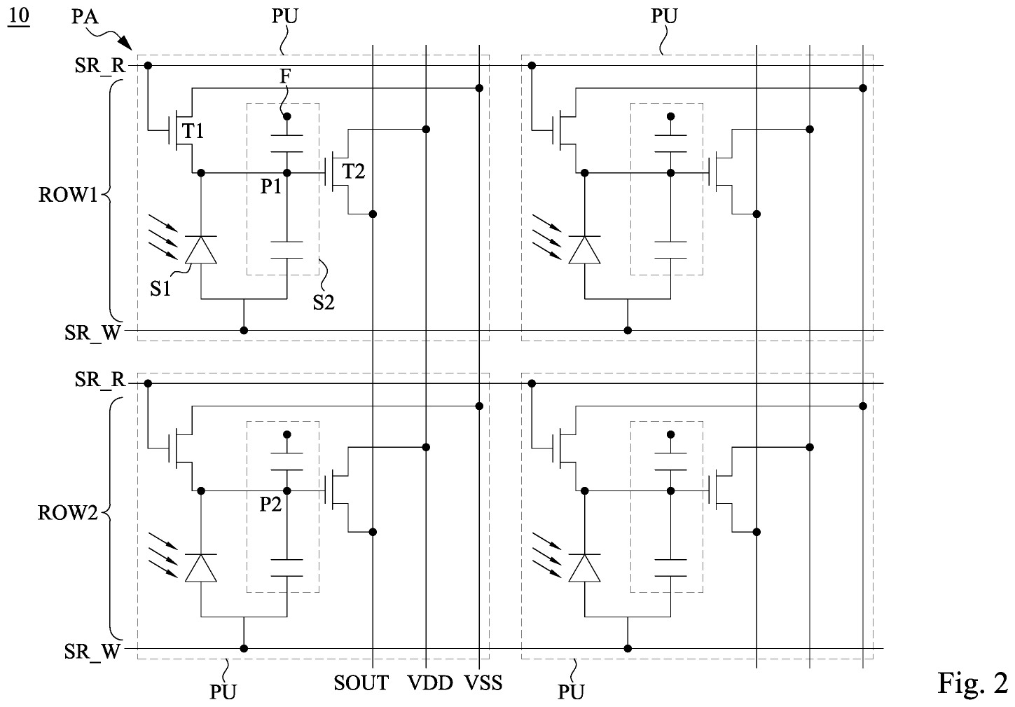

Reference is made to FIG. 2. FIG. 2 is a schematic diagram of a pixel array PA of a sensing panel 10 according to some embodiments of the present disclosure. As shown in FIG. 2, the sensing panel 10 includes a pixel array PA. The pixel array PA includes a plurality of pixel circuit units PU arranged in an array.

It should be understood that although only four pixel circuit units PU are shown in FIG. 2, the sensing panel 10 may include any number of pixel circuit units PU without departing from the scope of the present disclosure.

In the pixel array PA, the pixel circuit units PU are divided into multiple rows and arranged in parallel, such as a first row ROW1 and a second row ROW2 shown in FIG. 2. The sensing panel 10 sequentially scans the first row ROW1 and the second row ROW2 according to a scanning frequency for detection.

In some embodiments, the gates of the first thin film transistors T1 of the pixel circuit units PU in the same row receive the driving signal SR_R from the same gate driver.

It should be understood that other rows (not shown) may have the same configuration as the pixel circuit units PU of the first row ROW1 and the second row ROW2 and may be arranged consecutively to the first row ROW1 and the second row ROW2 to form the pixel array PA.

As shown in FIG. 2, the pixel circuit unit PU on the left in the first row ROW1 and the pixel circuit unit PU on the left in the second row ROW2 (that is, the pixel circuit unit PU arranged in the same column) share the same system voltage signal VSS and the same system voltage signal VDD.

To be more specific, the sources of the first thin film transistors T1 of the pixel circuit units PU arranged in the same column receive the same system voltage signal VSS. In some embodiments, the system voltage signal VSS may be a relatively low voltage signal or a signal ground. Similarly, the drains of the second thin film transistors T2 arranged in the same column receive the same system voltage signal VDD.

As aforementioned, the first thin film transistor T1, the second thin film transistor T2, the first sensor S1, and the second sensor S2 of the pixel circuit unit PU are coupled to each other through a node, such as the node P1 and the node P2 shown in FIG. 2.

It should be understood that the parasitic capacitances and/or connection resistances in different pixel circuit units PU may be slightly different. Therefore, during the signal reading process, the voltage of the node P1 may be different from the voltage of the node P2.

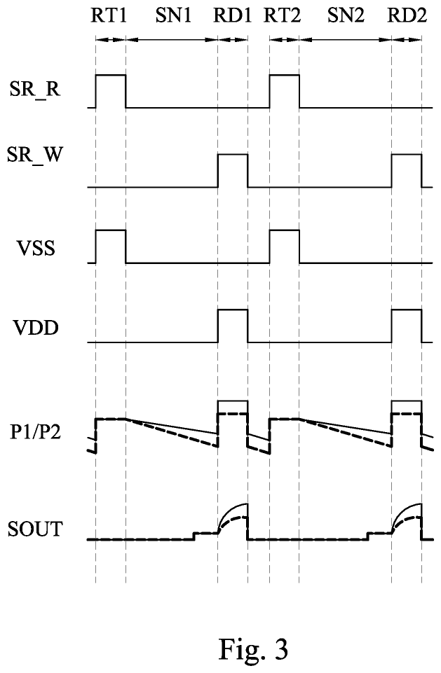

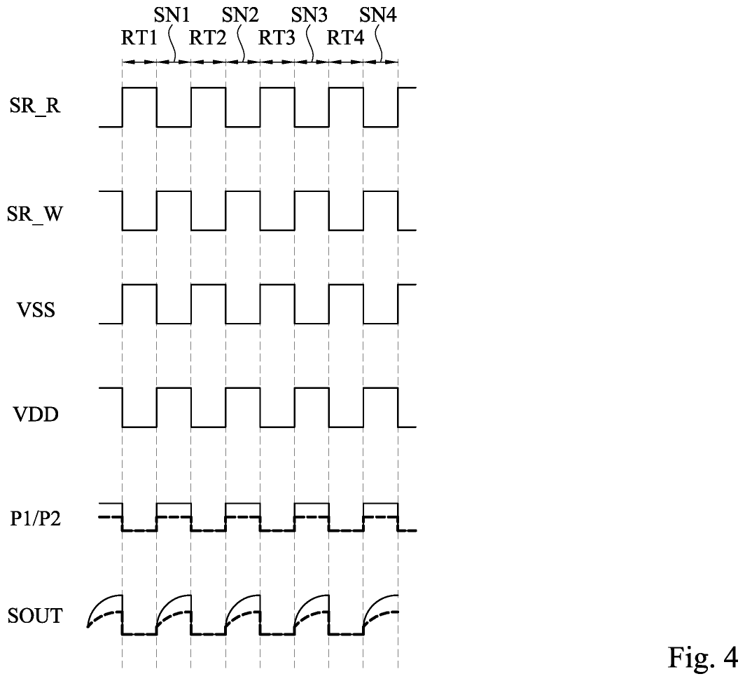

Reference is made to FIG. 3 and FIG. 4. FIG. 3 and FIG. 4 are sequence diagrams of the first sensor S1 and the second sensor S2 of the sensing panel 10 according to some embodiments of the present disclosure. In FIG. 3 and FIG. 4, the horizontal axis is the operation time of the first sensor S1 and the second sensor S2, and the vertical axis is the voltage value of the signal.

As aforementioned, the voltages of the node P1 and the node P2 may be different. Thus, in FIG. 3 and FIG. 4, the voltage of the node P1 is shown as a solid line, and the voltage of the node P2 is shown as a dotted line.

Reference is now made to FIG. 3. As shown in FIG. 3, at time RT1, the pixel circuit unit PU is reset. During this process, the driving signal SR_R is at a high-level voltage to turn on the first thin film transistor T1. The writing signal SR_W is at a relatively low voltage to cut off the first sensor S1 and turn off the second thin film transistor T2. In this way, the residual charge of the first sensor S1 can be released and the voltage of the node P1 can be reset to the voltage value of the system voltage signal VSS through the first thin film transistor T1.

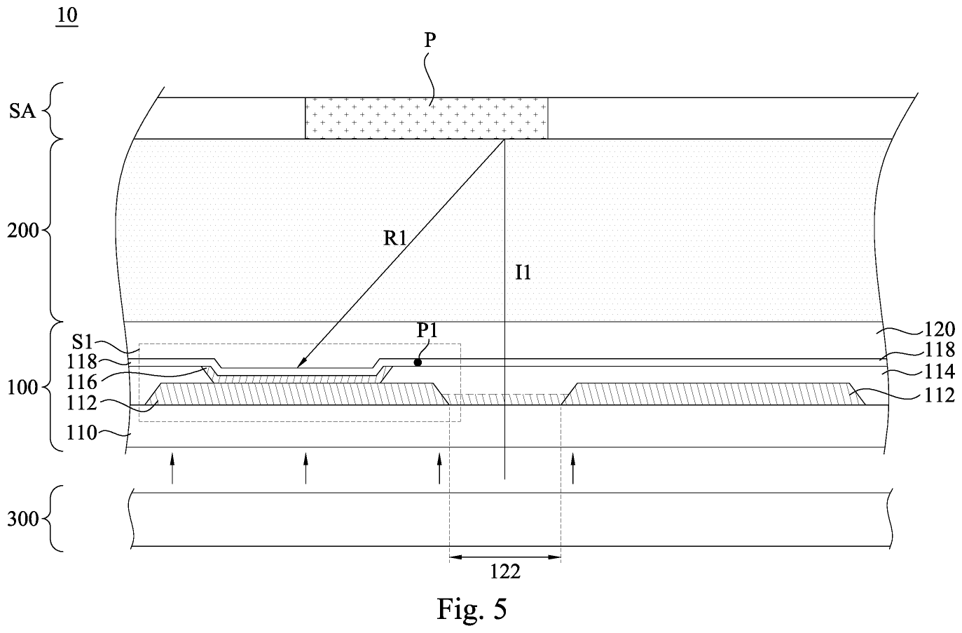

Then, at time SN1, the first sensor S1 senses the light. During this process, the driving signal SR_R is at a low-level voltage to turn off the first thin film transistor T1. At the same time, the writing signal SR_W is maintained at a low-level voltage and the first sensor S1 senses the external light. In some embodiments, the object to be detected is a hard copy such as a passport (for example, a passport P in FIG. 5). The images printed on the passport have different light absorptivity and reflectivity depending on the colors and the materials. For example, the shaded area and the blank area of the passport P shown in FIG. 5 are representative of images on the passport having different colors. Therefore, the first sensor S1 of each pixel circuit unit PU can detect different signals from different light rays through its light-sensing layer (e.g., the light-sensing layer 116 in FIG. 5), thereby achieving passport scanning. To be more specific, the light-sensing layer starts to discharge due to lighting. Therefore, the voltage value of the node P1 decreases, as shown in FIG. 3. The images on the passport have different light absorptivity and reflectivity, which causes the light-sensing layer of each pixel circuit unit PU to discharge at different levels and generate different voltage signals.

At time RD1, the pixel circuit unit PU reads the signal sensed by the first sensor S1. During this process, the driving signal SR_R is maintained at a low-level voltage to turn off the first thin film transistor T1, while the writing signal SR_W rises to a high-level voltage to switch on the first sensor S1 and makes the first sensor S1 raise the voltage level of the node P1 and provide the system voltage signal VDD to the second thin film transistor T2. The second thin film transistor T2 is turned on according to the sensing signal of the node P1 and generates a sensing result SOUT based on the system voltage signal VDD.

Next, the pixel circuit unit PU repeatedly undergoes the aforementioned resetting, sensing, and reading operations at time RT2, time SN2, and time RD2, which will not be repeated here.

It should be noted that the voltage of the node P2 and the voltage of the node P1 have similar trends as time goes, but are different in the voltage value. In some embodiments, the node P1 corresponds to a signal of low light reflectivity and the node P2 corresponds to a signal of high light reflectivity.

Reference is now made to FIG. 4. As shown in FIG. 4, at time RT1, the sensing capacitance of the second sensor S2 of the pixel circuit unit PU is charged. During this process, the driving signal SR_R is at a high-level voltage to turn on the first thin film transistor T1 and charge the second sensor S2, while the writing signal SR_W is a relatively low voltage to turn off the second thin film transistor T2.

At time SN1, the capacitance value of the second sensor S2 changes due to contact with the object to be detected. During this process, the driving signal SR_R is a low-level voltage to turn off the first thin film transistor T1. Meanwhile, the writing signal SR_W increases to a high-level voltage to turn on the second sensor S2 and make the second sensor S2 raise the voltage level of the node P1 and provide the system voltage signal VDD to the second thin film transistor T2. The second thin film transistor T2 is turned on according to the sensing signal of the node P1 and generates the sensing result SOUT based on the system voltage signal VDD.

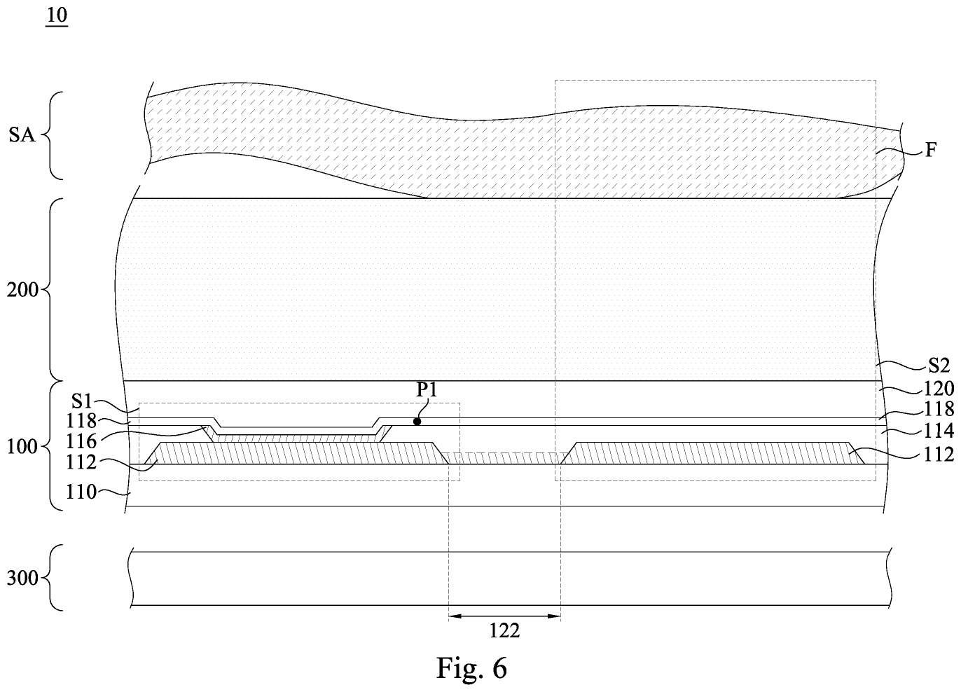

In some embodiments, the object to be detected is, for example, a finger (e.g. the finger F in FIG. 1 and FIG. 6). In the process of capacitive sensing, the finger can be equivalent to an electrode, which may be considered connecting another capacitance in parallel in the circuit. However, due to the different capacitance values of the peaks and troughs of the fingerprint, each pixel circuit unit PU has a different discharge rate at time SN1 and outputs a different voltage signal. In this way, a fingerprint image can be formed based on the detected peaks and troughs. Then, the features of the fingerprint image can be compared with fingerprints stored in a database and the owner of the fingerprint image may be determined.

Similarly, the pixel circuit unit PU then repeatedly performs the aforementioned charging and discharging in time RT2 and time SN2, time RT3 and time SN3, as well as time RT4 and time SN4, respectively, which will not be described again.

Reference is made to FIG. 5 and FIG. 6. FIG. 5 and FIG. 6 are partial cross-sectional views of the sensing panel 10 according to some embodiments of the present disclosure. The sensing panel 10 includes an array substrate 100. In some embodiments, the sensing panel 10 further includes a protective layer 200. As shown in FIG. 5 and FIG. 6, the protective layer 200 is disposed above the array substrate 100. In some embodiments, the protective layer 200 may include glass or other transparent materials.

In some embodiments, the sensing panel 10 further includes a light source module 300. As shown in FIG. 5 and FIG. 6, the light source module 300 is disposed on a side of the array substrate 100 opposite to the protective layer 200. In other words, the array substrate 100 is disposed between the protective layer 200 and the light source module 300.

The array substrate 100 includes a substrate 110. In some embodiments, the substrate 110 includes glass, quartz, plastic, polymer substrate, or other suitable light-transmitting materials.

The array substrate 100 further includes a first switching element and a second switching element (not shown in FIG. 5 and FIG. 6). As aforementioned, in some embodiments, the first switching element is the first thin film transistor T1, and the second switching element is the second thin film transistor T2. The first thin film transistor T1 and the second thin film transistor T2 include a source, a drain, and a gate, respectively.

As shown in FIG. 5 and FIG. 6, the array substrate 100 further includes a first sensor S1 and a second sensor S2.

As shown in FIG. 5, in some embodiments, the first sensor S1 is disposed above the substrate 110. In some embodiments, the first sensor S1 includes a metal electrode layer 112, a light-sensing layer 116, and a transparent electrode layer 118. As aforementioned, the first sensor S1 is a light-sensing element configured to receive a light and correspondingly generate sensing signals. As shown in FIG. 5, the light-sensing layer 116 is disposed on the metal electrode layer 112, and the transparent electrode layer 118 is disposed on the light-sensing layer 116.

Moreover, the transparent electrode layer 118 acts as a cathode of the first sensor S1. An example position of a node P1 is shown in FIG. 5. The metal electrode layer 112 acts as an anode of the first sensor S1 and is configured to receive the writing signal SR_W (as shown in FIG. 1).

As shown in FIG. 6, in some embodiments, the second sensor S2 is disposed above the substrate 110. In some embodiments, the second sensor S2 includes a metal electrode layer 112, a first insulating layer 114, a transparent electrode layer 118, and a second insulating layer 120. As aforementioned, the second sensor S2 is a capacitive sensing element configured to contact the object to be detected, such as the finger F in FIG. 6, and generate the sensing signal based on the capacitance value between the object and the metal electrode layer 112.

To be more specific, when the finger F contacts the protective layer 200, it is equivalent to introducing the capacitance of the finger F, the capacitance of the protective layer 200, and the capacitance of the second insulating layer 120 into the circuit through the node P1. At the same time, another capacitance (e.g., the capacitance of the first insulating layer 114) exists between the node P1 and the metal electrode layer 112. The peaks and troughs of the fingerprint have different capacitance values, thus generating different sensing signals during the process. Meanwhile, the light source module 300 may be on or off.

As shown in FIG. 6, the first insulating layer 114 is disposed on the metal electrode layer 112, the transparent electrode layer 118 is disposed on the first insulating layer 114, and the second insulating layer 120 is disposed on the transparent electrode layer 118.

Similarly, an example position of the node P1 is shown in FIG. 6. In this way, the second sensor S2 is coupled to the cathode of the first sensor S1 through the node P1.

In order to couple the second sensor S2 to the first sensor S1, the metal electrode layer 112 of the second sensor S2 and the metal electrode layer 112 of the first sensor S1 are connected at equal potential. For example, in some embodiments, the metal electrode layer 112 of the second sensor S2 and the metal electrode layer 112 of the first sensor S1 may be in contact with each other. Similarly, in some embodiments, the transparent electrode layer 118 of the second sensor S2 and the transparent electrode layer 118 of the first sensor S1 may be in contact with each other.

Furthermore, in some embodiments, the metal electrode layer 112 of the second sensor S2 and the metal electrode layer 112 of the first sensor S1 may be a continuous structure. Similarly, in some embodiments, the transparent electrode layer 118 of the second sensor S2 and the transparent electrode layer 118 of the first sensor S1 may be a continuous structure. For example, as shown in FIG. 5 and FIG. 6, the metal electrode layer 112 of the first sensor S1 and the metal electrode layer 112 of the second sensor S2 are connected through the hatched area shown by dotted lines.

It should be noted that, as shown in FIG. 5 and FIG. 6, a height of the metal electrode layer 112 is set to be greater than a height of the hatched area, so that the metal electrode layer 112 can be used as a sensing portion. In addition, in the direction pointing into the plane of paper, the metal electrode layer 112 and the hatched area may have different characteristic lengths. For example, a length of the hatched area is smaller than a length of the metal electrode layer 112 to allow light transmission shown in the light-transmitting area 122 in FIG. 5. The characteristics of the light-transmitting area 122 will be described in detail in following paragraphs.

In this embodiment, the transparent electrode layer 118 covers the light-sensing layer 116 of the first sensor S1 and the first insulating layer 114 of the second sensor S2. In some embodiments, the first insulating layer 114 of the second sensor S2 laterally surrounds the light-sensing layer 116 of the first sensor S1. In some embodiments, the light-sensing layer 116 of the first sensor S1 and the first insulating layer 114 of the second sensor S2 jointly cover the metal electrode layer 112.

In addition, in some embodiments, the metal electrode layer 112 of the second sensor S2 and the metal electrode layer 112 of the first sensor S1 may be electrically connected through a wiring layer (not shown). Similarly, in some embodiments, the transparent electrode layer 118 of the second sensor S2 and the transparent electrode layer 118 of the first sensor S1 may be electrically connected through a wiring layer (not shown).

As shown in FIG. 5 and FIG. 6, a side of the transparent electrode layer 118 away from the substrate 110 is a sensing area SA. The object to be detected (such as the passport P in FIG. 5 or the finger F in FIG. 6) is disposed in the sensing area SA. The light source module 300 is further configured to emit a light toward the sensing area SA, so that the light is reflected from the object disposed in the sensing area SA through the transparent electrode layer 118 to the light-sensing layer 116. In other words, the light source module 300 may be disposed on a side of the substrate 110 away from the sensing area SA.

In some embodiments, the metal electrode layer 112 includes data lines, sources, drains, and gates of the first thin film transistor T1 and the second thin film transistor T2. The material of the metal electrode layer 112 may include titanium (Ti), aluminum (Al), tungsten (W), molybdenum (Mo), tantalum (Ta), copper (Cu), gold (Au), silver (As), or alloys thereof, but this disclosure is not limited thereto.

As shown in FIG. 5 and FIG. 6, the first insulating layer 114 has an opening. The light-sensing layer 116 is disposed on the metal electrode layer 112 through the opening and is electrically connected to the metal electrode layer 112. Generally speaking, the dimensions of the light-sensing layer 116 define the area of the first sensor S1. Furthermore, in some embodiments, as shown in FIG. 5 and FIG. 6, the area of the light-sensing layer 116 is smaller than the area of the metal electrode layer 112. In some embodiments, the light-sensing layer 116 includes silicon-rich oxide (SRO), but the present disclosure is not limited thereto.

As shown in FIG. 5 and FIG. 6, the transparent electrode layer 118 is formed above the first insulating layer 114 and covers the light-sensing layer 116. The light-sensing layer 116 is electrically connected to the transparent electrode layer 118. In some embodiments, the transparent electrode layer 118 includes metal oxides such as indium tin oxide (ITO), indium zinc oxide (IZO), aluminum zinc oxide (AZO), indium oxide (InO), gallium oxide (GaO), organic transparent conductive materials, or other suitable transparent conductive materials.

The second insulating layer 120 is disposed above the substrate 110. The second insulating layer 120 can be used as a planarization layer to eliminate height differences between the underlying layers and protect the structures. In some embodiments, the second insulating layer 120 may be a single-layer or multi-layer structure.

In some embodiments, the first insulating layer 114 and the second insulating layer 120 may be transparent, insulating materials. For example, inorganic materials such as silicon oxide, silicon nitride, silicon oxynitride, or combinations thereof, organic materials such as photoresist, polyimide (PI), polyester, benzocyclobutene (BCB), polymethylmethacrylate (PMMA), poly(4-vinylphenol) (PVP), polyvinyl alcohol (PVA), polytetrafluorothene (PTFE), epoxy, perfluorocyclobutane (PFCB), acrylic, siloxane, or combinations thereof.

In addition, as shown in FIG. 5 and FIG. 6, the first sensor S1 has a light-transmitting area 122 around it. Specifically, when the object to be detected is the passport P, the light source module 300 emits an incident light 11 toward the sensing area SA. The incident light 11 is transmitted toward the passport P through the light-transmitting area 122. The passport P absorbs a portion of the incident light 11 and reflects a reflected light R1 toward the light-sensing layer 116 of the first sensor S1. When the light-sensing layer 116 receives the reflected light R1, the light-sensing material is excited by the reflected light R1 to form a photocurrent, that is, a light-sensing signal.

In some embodiments, the light source module 300 may be a direct type backlight module or an edge type backlight module, but the disclosure is not limited thereto. In some embodiments, the light source module 300 may also be a plurality of light-emitting elements integrated inside the array substrate 100, such as micro light-emitting diodes (micro LED, μLED) or other appropriate types of light sources.

In some embodiments, in a normal direction of the substrate 110, the protective layer 200 right above the light-transmitting area 122 and the second insulating layer 120 are tightly coupled without gaps, so that the incident light 11 transmitted from the light-transmitting area 122 toward the sensing area SA will not change its propagation path due to changes in the propagation medium.

According to the foregoing recitations of the embodiments of the disclosure, it may be seen that in the sensing panels of some embodiments of the present disclosure, by coupling the light-sensing element and the capacitive sensing element to the pixel circuit unit, both light-sensing and capacitive sensing functions can be included. As a result, when scanning images of hard copies such as passports, the light source module is activated and the light-sensing element is used for scanning. When identifying fingerprints, the capacitive sensing with better resolution and anti-counterfeiting effect is switched on. Compared with common sensing panels that only have light-sensing functions, resolution may be improved and anti-counterfeiting effects may be achieved in the sensing panels of some embodiments of the present disclosure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure covers modifications and variations of this disclosure provided they fall within the scope of the following claims.

What is claimed is:

1. A sensing panel, comprising:
a substrate;
a first sensor disposed above the substrate, comprising a first metal electrode layer, a light-sensing layer, and a first transparent electrode layer, and configured to receive a light and correspondingly generate a first sensing signal, wherein the light-sensing layer is disposed on the first metal electrode layer, and the first transparent electrode layer is disposed on the light-sensing layer;
a second sensor disposed above the substrate, comprising a second metal electrode layer, an insulating layer, and a second transparent electrode layer, and configured to contact an object and generate a second sensing signal based on a capacitance value between the object and the second metal electrode layer, wherein the insulating layer is disposed on the second metal electrode layer, and the second transparent electrode layer is disposed on the insulating layer; and
a first switching element and a second switching element,
wherein the first metal electrode layer is electrically connected to the second metal electrode layer and further to the first switching element and the second switching element, and the first transparent electrode layer is electrically connected to the second transparent electrode layer.

2. The sensing panel according to claim 1, wherein the light-sensing layer comprises silicon-rich oxide.

3. The sensing panel according to claim 1, wherein the first transparent electrode layer and the second transparent electrode layer are in contact with each other.

4. The sensing panel according to claim 1, wherein the first transparent electrode layer and the second transparent electrode layer are connected to form a transparent conductive layer and the transparent conductive layer covers the light-sensing layer of the first sensor and the insulating layer of the second sensor.

5. The sensing panel according to claim 1, wherein the light-sensing layer of the first sensor and the insulating layer of the second sensor jointly cover the first metal electrode layer and the second metal electrode layer.

6. The sensing panel according to claim 1, wherein the first switching element and the second switching element are thin film transistors, and the first switching element and the second switching element comprise a source, a drain, and a gate, respectively, wherein the first sensor and the second sensor are electrically connected the drain of the first switching element and the gate of the second switching element.

7. The sensing panel according to claim 1, further comprising a light source module, wherein a side of the first transparent electrode layer and the second transparent electrode layer away from the substrate is a sensing area, the object is disposed in the sensing area, and the light source module is configured to emit the light toward the sensing area, so that the light is reflected from the object through the first transparent electrode layer to the light-sensing layer.

8. The sensing panel according to claim 7, wherein the light source module is disposed on a side of the substrate away from the sensing area.

9. The sensing panel according to claim 1, wherein the insulating layer of the second sensor laterally surrounds the light-sensing layer of the first sensor.

10. A sensing panel, comprising:
a substrate; and
a pixel array comprising a plurality of pixel circuit units arranged in an array, each of the pixel circuit units comprising:
a metal layer disposed above the substrate;
a transparent conductive layer disposed above the metal layer;
a light-sensing layer disposed between the metal layer and the transparent conductive layer and configured to receive a light;
an insulating layer disposed between the metal layer and the transparent conductive layer and laterally surrounds the light-sensing layer;
a first thin film transistor comprising a source, a drain, and a gate; and
a second thin film transistor comprising a source, a drain, and a gate,
wherein the transparent conductive layer is electrically connected to the drain of the first thin film transistor and the gate of the second thin film transistor.

11. The sensing panel according to claim 10, wherein the light-sensing layer comprises silicon-rich oxide.

12. The sensing panel according to claim 10, wherein the gate of the first thin film transistor is configured to receive a driving signal.

13. The sensing panel according to claim 10, wherein the source of the first thin film transistor is configured to receive a system voltage.

14. The sensing panel according to claim 10, wherein the drain of the second thin film transistor is configured to receive a system voltage.

15. The sensing panel according to claim 10, further comprising a light source module, wherein a side of the transparent conductive layer away from the substrate is a sensing area, and the light source module is configured to emit the light towards the sensing area, so that the light is reflected from an object disposed in the sensing area through the transparent conductive layer to the light-sensing layer.

16. The sensing panel according to claim 15, wherein the light source module is disposed on a side of the substrate away from the sensing area.

17. The sensing panel according to claim 10, wherein the light-sensing layer and the insulating layer jointly cover the metal layer.
